(19) United States
(12) Patent Application Publication
(10) Pub. No.: US 2013/0113039 A1
(43) Pub. Date: May 9, 2013

(54) SEMICONDUCTOR DEVICE

(71) Applicants: Takeru MATSUOKA, Hyogo-ken (JP); Kentaro ICHINOSEKI, Hyogo-ken (JP); Shigeaki HAYASE, Hyoko-ken (JP); Nobuyuki SATO, Hyogo-ken (JP)

(72) Inventors: Takeru MATSUOKA, Hyogo-ken (JP); Kentaro ICHINOSEKI, Hyogo-ken (JP); Shigeaki HAYASE, Hyoko-ken (JP); Nobuyuki SATO, Hyogo-ken (JP)

(73) Assignee: KABUSHIKI KAISHA TOSHIBA, Tokyo (JP)

(21) Appl. No.: 13/607,372

(22) Filed: Sep. 7, 2012

(30) Foreign Application Priority Data
Sep. 20, 2011 (JP) P2011-204122

(51) Int. Cl. H01L 29/78

(52) U.S. Cl. CPC H01L 29/7813
USPC 257/330; 438/270

(57) ABSTRACT

A semiconductor device provides a MOSFET having first and second regions. In the first region, a plurality of unit cells of the MOSFET device are provided. At the end of the plurality of the unit cells, a termination cell is provided. An n type layer underlies the unit cells, between the unit cells and an underlying electrode. In the unit cell region, this n doped layer is dually doped with impurities at two different densities, whereas, adjacent the termination cell, a different paradigm is provided. In one aspect, only one of the two n doped layers extends along a side of the termination cell. In a second aspect, the termination unit is in contact with an oppositely doped layer as compared to the impurities in the dual doped layer. In this way, breakdown voltage may be maintained while on-resistance is simultaneously reduced.

### CROSS-REFERENCE TO RELATED APPLICATION

This application is based upon and claims the benefit of priority from Japanese Patent Application No. 2011-204122, filed Sep. 20, 2011; the entire contents of which are incorporated herein by reference.

### FIELD

Embodiments described herein relate to a semiconductor device.

### BACKGROUND

In recent years, in addition to the switching power supply market which requires devices with high current and high voltage capability, demand for a power MOSFET in an energy-saving switching power supply market, first for laptops and now in mobile communication equipment and the like, has arisen. A power MOSFET is used for synchronous rectification in AC-DC converters in a power supply. In this case, in addition to a breakdown voltage of about 80-250 V, low on-resistance structure and switching loss reduction are required.

Here, a MOSFET having a trench MOS structure is used in order to reduce on-resistance of the power MOSFET. This MOSFET of trench MOS structure has a plurality of trenches at predetermined interval on a semiconductor layer which becomes a channel region. On an inner wall of this trench, an insulating film which is the gate insulating film is formed, and through this insulating film, a conductive film providing the gate electrode is formed inside the trench. By miniaturizing the width of the trench or the width of the semiconductor layer between the trenches, channel density in internal elements can be improved.

In the case where a MOSFET having reduced on-resistance using the structure described above, the breakdown voltage of an end region adjacent thereto has to be ensured, which has been problematic in current designs.

### DESCRIPTION OF THE DRAWINGS

FIGS. 1A and 1B are cross-sectional views of the semiconductor device according to a first, prior art, comparative example.

FIGS. 2A and 2B are graphs showing the impurity concentration of the semiconductor device according to the first, prior art, comparative example.

FIGS. 3A and 3B are cross-sectional views of the semiconductor device according to a second, prior art, comparative example.

FIGS. 4A and 4B are graphs showing the impurity concentration of the semiconductor device according to the second, prior art, comparative example.

FIGS. 5A and 5B are cross-sectional views of a semiconductor device according to a first embodiment.

FIGS. 6A and 6B are graphs showing the impurity concentration of the semiconductor device according to the first embodiment.

FIGS. 7A and 7B are cross-sectional views of a semiconductor device according to a second embodiment.

FIGS. 8A and 8B are graphs showing the impurity concentration of the semiconductor device according to the second embodiment.

### DETAILED DESCRIPTION

In general, according to one embodiment, the semiconductor device according to the first embodiment will be explained by referring to the attached and referenced drawing figures. After having explained the schematic configuration of a semiconductor device according to the first and the second prior art comparative examples, a semiconductor device according to the embodiments, will be described.

According to the embodiment, there is provided a semiconductor device which enables an improvement of breakdown voltage and a reduction in on-resistance.

A semiconductor device according to a first embodiment: includes: a first region which functions as a MOSFET; and a second region which is adjacent to the first region; the first region comprising, a drain electrode of the MOSFET; a semiconductor substrate of a first conductivity type which has a first impurity concentration while being electrically connected to the drain electrode; a first semiconductor layer (formed on top of the semiconductor substrate) of the first conductivity type which has a second impurity concentration which is lower than the first impurity concentration; a second semiconductor layer (formed on the surface of the first semiconductor layer) of the first conductivity type which has a third impurity concentration which is lower than the first impurity concentration but higher than the second impurity concentration; a plurality of first trenches formed on the upper side of the second semiconductor layer; a third semiconductor layer (formed on the surface of the second semiconductor layer) of the second conductivity type, which is adjacent to the first trenches; a fourth semiconductor layer (formed on the surface of the third semiconductor layer) of the first conductivity type which is adjacent to the first trenches; a first insulating layer which is formed along inner walls of the first trenches; a gate electrode layer (provided in the middle of the insulating layer) which functions as a MOSFET gate electrode and is opposed to the third semiconductor layer through the first insulating layer; a trench source electrode layer which is formed in order to embed the first trenches through the first insulating layer; and a MOSFET source electrode which contacts the fourth semiconductor layer and which is electrically connected to the trench source electrode layer, and the second region comprising: the semiconductor substrate; the first semiconductor layer; the first insulating layer formed in order to extend to the upper face of the first semiconductor layer; and the source electrode formed in order to extend to the upper face of the first insulating layer, wherein the first semiconductor layer of the second region has the second impurity concentration.

### Comparative Example 1

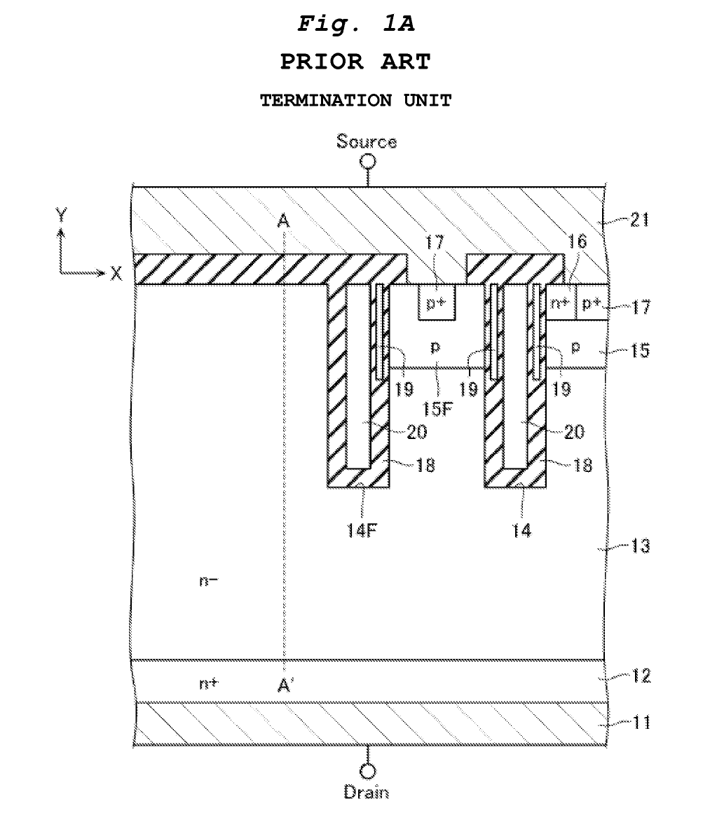

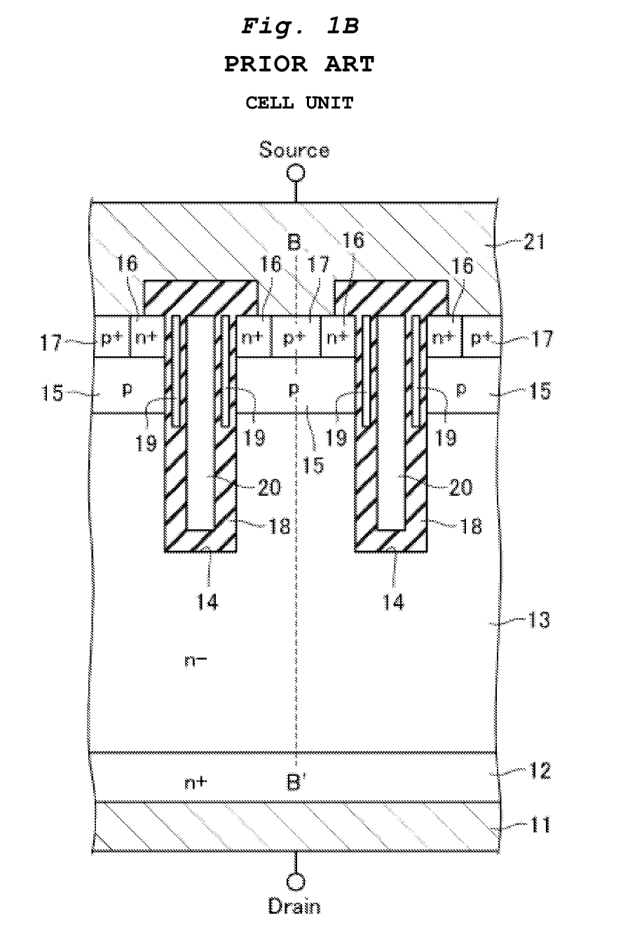

FIGS. 1A and 1B, explain the semiconductor device according to the first comparative example. As shown in FIG. 1A and FIG. 1B, the semiconductor device according to the first comparative example, includes a cell unit which functions as a MOSFET and a termination unit provided in the periphery of the cell unit.

First, the cell unit will be described. As shown in FIG. 1B, the cell unit includes a drain electrode 11, an n+ type semiconductor substrate 12, an n− type epitaxial layer 13 and multiple trenches 14 extending inwardly of the n− type epitaxial layer and provided therein in predetermined intervals in direction X.

The n+ type semiconductor substrate 12 is provided on drain electrode 11 and is electrically connected to drain electrode 11. The n+ type semiconductor substrate 12 can have an impurity concentration of 1×10²⁰ [atoms/cm³]. The n− type epitaxial layer 13 is formed on n+ type semiconductor substrate 12. The n− type epitaxial layer 13 is smaller than n+ type semiconductor substrate 12, it can have an impurity concentration of 1×10¹⁵ [atoms/cm³] for example. Each trench 14 extends from the upper side of n− type epitaxial layer 13 toward the lower, substrate 12 side of the n− type epitaxial layer, but terminates within the n− type epitaxial layer 13. As shown in FIG. 1B, the cell unit includes p type base layer 15, n+ type source layer 16 and p+ type contact layer 17. P type base layer 15 is adjacent to trenches 14 and is formed on n− type epitaxial layer 13 on the side thereof opposite to substrate 12. p type base layer 15 can have a degree of impurity concentration of, 1×10¹⁶ to 1×10¹⁷ [atoms/cm³]. p type base layer 15 functions as MOSFET channels. n+ type source layer 16 is formed on p type base layer 15 and disposed on either side of the trenches. n+ type source layer 16 can have, for example, a degree of impurity concentration of 1×10²⁰ [atoms/cm]. p+ type contact layer 17 is formed on p type base layer 15. p+ type contact layer 17 is adjacent to n+ type base layer 16 between trenches 14, such that n+ type source layer is disposed between p+ contact layer 17 and the adjacent trench 14. P+ type contact layer 17 has a higher impurity concentration than that of p type base layer 15. For example, it can have a degree of impurity concentration of 1×10²⁰ [atoms/cm³].

In FIG. 1B, the trenches 14 of the cell unit are lined and capped with an insulating layer 18, having a gate electrode layer 19 formed and enclosed within the insulating layer 18 on either side of the trenches 14, and disposed generally adjacent to the n+ source layers 16 and p type base layers 15, a trench source electrode extending inwardly of the trench and generally filling the bounds of the insulating layer 18 within the trench 14, and a source electrode layer 21 overlying trenches 14. The insulating layer 18 is formed along inner walls of each trench 14 by using, for example, Silicon oxide (SiO₂). The gate electrode layer 19 is provided within the insulating layer 18 and adjacent to a side surface of p type base layer 15 through the insulating layer 18. The gate electrode layer 19 functions as a MOSFET gate. The gate electrode layer 19 is composed of polysilicon, for example. The trench source electrode layer 20 is formed within the trenches within the insulating layer 18. The upper face of trench source electrode layer 20 is covered or capped by the insulating layer 18. The trench source electrode layer 20 is composed of polysilicon, for example. The source electrode 21 contacts the upper face of n+ type source layer 16 and the upper face of p+ type contact layer 17. The source electrode 21 is electrically connected to trench source electrode layer 20 through a connection (not shown). More precisely, the trench source electrode layer 20 is at the same potential as the source electrode 21. Thanks to this, the electric field concentration is relaxed and the breakdown voltage of the cell unit can be improved.

Next, the termination unit will be described. As shown in FIG. 1A, in the termination unit, the trenches 14 which were arranged consecutively in the n− layer 13 terminate in a final trench 14F. The termination unit includes n+ type semiconductor substrate 12 having an n− type epitaxial layer 13 formed thereon, and a drain electrode 11 formed on the underside of the substrate 12 as in the unit cell region of FIG. 1B. Note that in the termination unit, on top of p type base layer 15F which is located intermediate of the final two trenches 14, 14F, the n+ type source layer 16 is not formed but the p+ contact layer is formed intermediate of, but spaced by the p layer from, the trenches 14. Additionally, gate electrode 19 is provided only on the side of the final trench 14F facing the adjacent trench 14 which is on the outermost side of the termination unit.

The insulating layer 18 within and capping the trenches in the cell units is extended, in the termination unit, over the n− type epitaxial layer 13 in a direction away from the last unit cell. The source electrode 21 is formed thereover, and likewise extends over the insulating layer in the direction away from the unit cells.

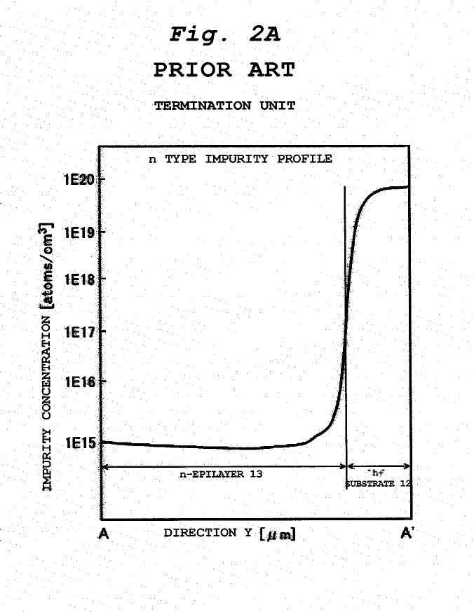

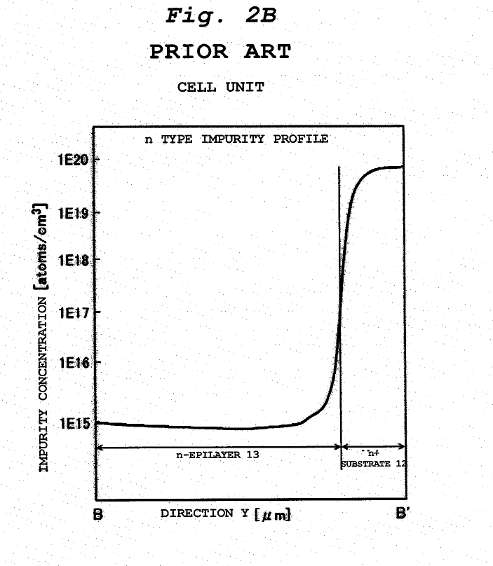

FIGS. 2A and 2B are graphs showing n type impurity concentration along the lines A-A′ and B-B′ in the termination unit and the cell unit of the first comparative example shown in FIGS. 1A and 1B. The vertical axis of FIGS. 2A and 2B show the impurity concentration and the horizontal axis shows the position of direction Y shown in FIGS. 1A and 1B. As shown in FIGS. 2A and 2B, n+ type semiconductor substrate 12 in the termination unit and in the cell unit can have, an n type impurity concentration of 1×10²⁰[atoms/cm³] and n− type epitaxial layer 13 can have an n type impurity concentration of 1×10¹⁵[atoms/cm³]. However, the impurity concentration curves showing n type impurity concentration in the termination unit and in the cell unit are substantially the same.

As one of performances required when using this semiconductor device as a switching element, avalanche resistance is required. This avalanche resistance can be improved by structural design in order to make the breakdown voltage of the termination unit higher than the breakdown voltage of the cell unit. According to the first comparative example, in order to make the breakdown voltage of termination unit higher than that of the cell unit, it is necessary to lower the concentration of n− type epitaxial layer 13, but in that case, as on-resistance increases, the performance of the semiconductor device will be lowered.

### Comparative Example 2

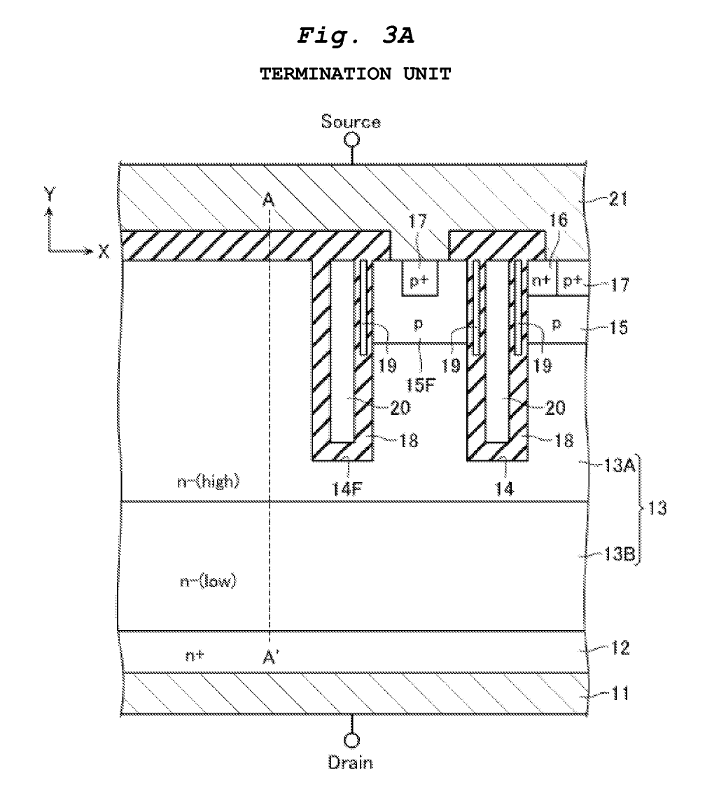

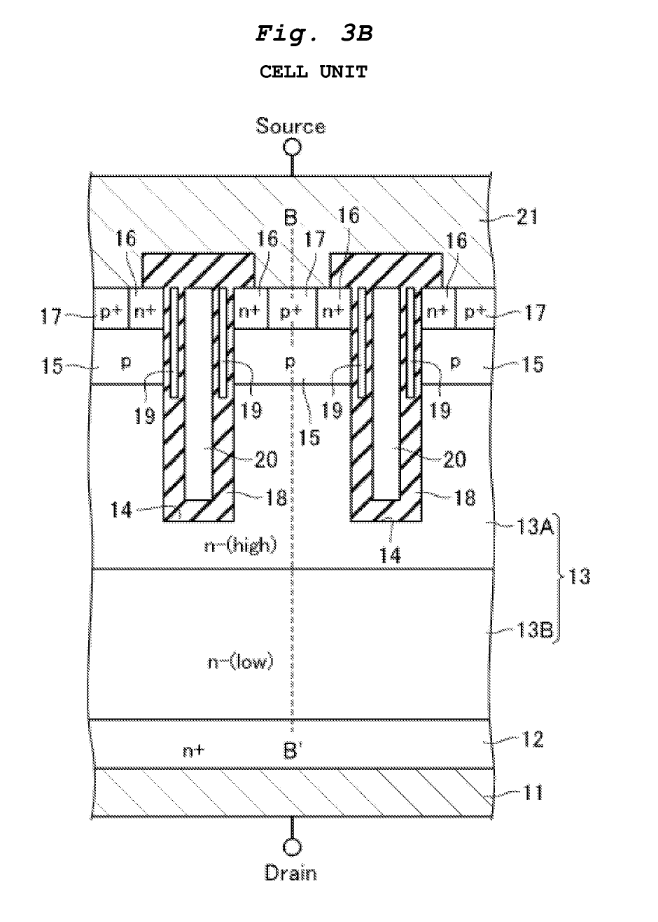

Now referring to FIGS. 3A and 3B, we are going to explain the semiconductor device by referring to a second prior art comparative example. As shown in FIG. 3A and FIG. 3B, the semiconductor device according to the second comparative example also includes the cell unit which functions as a MOSFET and the termination unit which is provided on the periphery of the cell unit. It should be noted that in the second comparative example, shown in FIGS. 3A and 3B, the parts that have the same structure as the first comparative example and duplicate descriptions denoted by the same reference numerals, have be omitted.

The primary difference in the semiconductor device in the second comparative example and the semiconductor device in first comparative example, is that the n− type epitaxial layer 13 of the cell unit and the termination unit is provided in a two-layer structure which has high concentration n− type epitaxial layer 13A and low concentration n− type epitaxial layer 13B. The low concentration n− type epitaxial layer 13B has the same degree of impurity concentration as n− type epitaxial layer 13 in the first comparative example, for example, it has a degree of impurity concentration of 1×10¹⁵[atoms/cm³]. Then, high concentration n− type epitaxial layer 13A has a large impurity concentration with regard to low concentration n− type epitaxial layer 13B, for example, the degree of its impurity concentration is 1×10¹⁶[atoms/cm³]. In this prior art device, the trenches 14 extend into, but do not extend through, the high impurity concentration n− layer 13A, and thus are not in direct contact with the underlying low impurity concentration n-layer 13B This difference in impurity concentration between high concentration n− type epitaxial layer 13A and low concentration n− type epitaxial layer 13B is realized by repeating the growth of epitaxial layer in different conditions on top of n+ type semiconductor substrate 12 or changing implant conditions of n− type impurities to form the epitaxial layer or the like. By using a bi-layer having different concentrations for the n− type impurity, it is possible to reduce the on-resistance of the device.

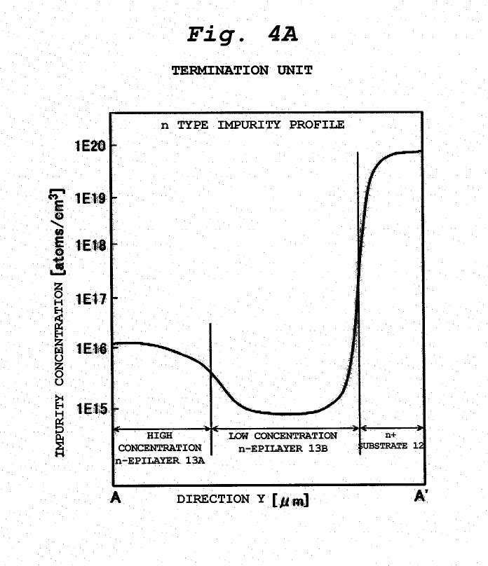

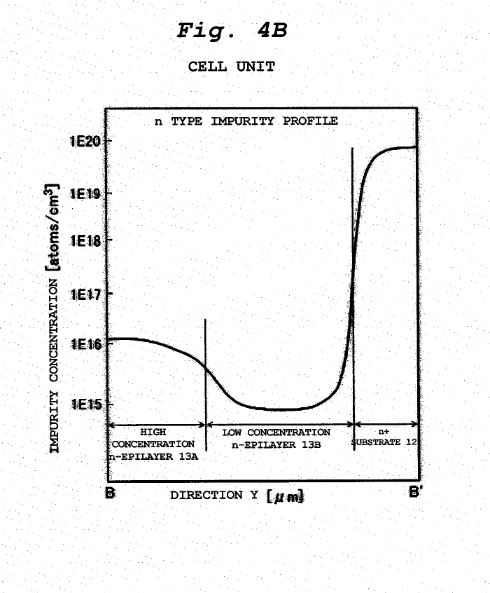

FIGS. 4A and 4B are graphs showing n type impurity concentration along the lines A-A′ and B-B′ on the termination unit and the final cell unit of the second comparative example as shown in FIGS. 3A and 3B. The vertical axis of FIGS. 4A and 4B show impurity concentrations and the horizontal axis show the position of direction Y shown in FIGS. 3A and 3B. As shown in FIGS. 4A and 4B, n+ type semiconductor substrate 12 in the termination unit and the cell unit has an n− type impurity concentration on the order of 1×10²° atoms/cm³. Low concentration n− type epitaxial layer 13B has an n type impurity concentration of 1×10¹⁵ atoms/cm² and high concentration n-type epitaxial layer 13A has an n type impurity concentration of 1×10¹⁶ atoms/cm³, for example. The impurity concentration curves showing n type impurity concentration of the termination unit and the cell unit are substantially the same.

In the semiconductor device in the second comparative example, where the n− type epitaxial layer 13 is divided into two layers which are a high concentration n− type epitaxial layer 13A and a low concentration n− type epitaxial layer 13B., on-resistance is reduced because a high concentration n− type epitaxial layer 13A extends and is positioned immediately below trenches 14. However, using this architecture for the n− type epitaxial layer, the breakdown voltage of the termination unit has a lower field plate effect than the cell unit, which is also lower than the voltage of the cell unit, and avalanche resistance of the termination unit is thereby reduced.

### Embodiment 1

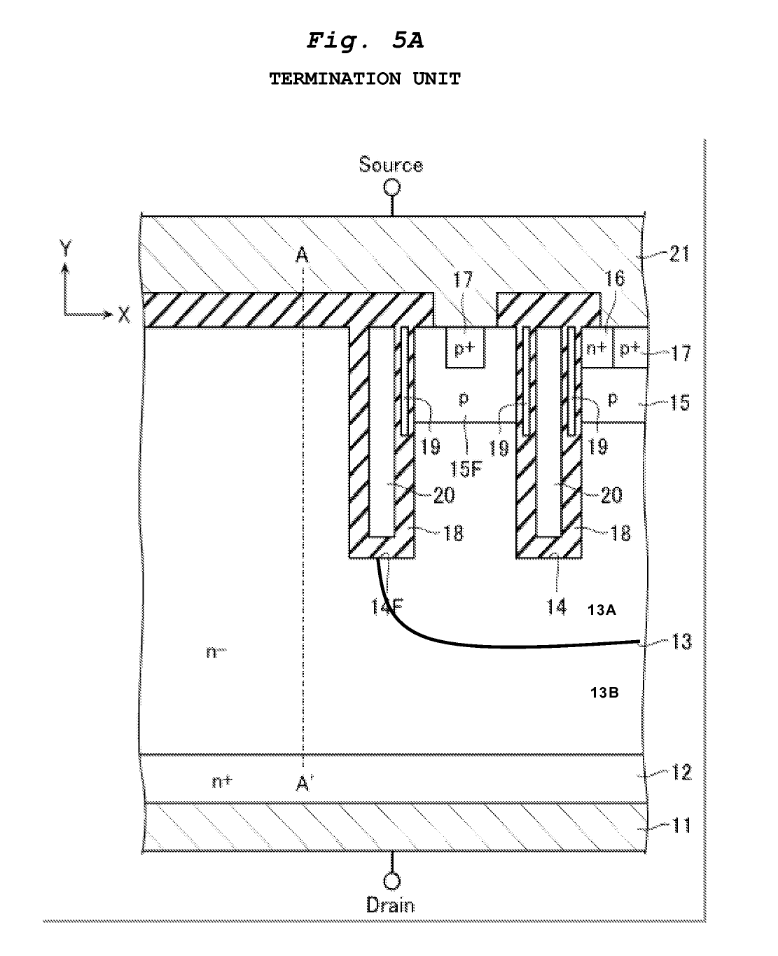

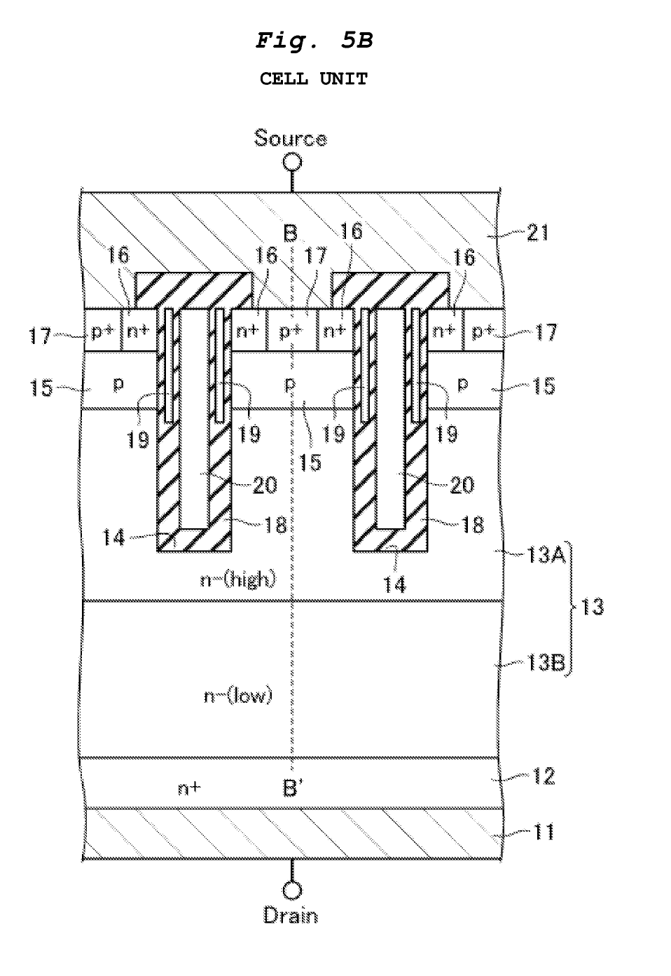

Referring now to FIGS. 5A and 5B, a first embodiment of the semiconductor device hereof is described. The semiconductor device of FIG. 5A and FIG. 5B includes the cell unit which functions as a MOSFET and the termination unit provided on the periphery or end of the cell unit. It should be noted that, in the first embodiment shown in FIGS. 5A and 5B, the parts that have the same structure as the first and the second comparative examples and duplicate descriptions denoted by the same-reference numerals, will be omitted.

In the semiconductor device according to the first embodiment, n− type epitaxial layer 13 in the cell unit is provided in a two-layer structure including high impurity concentration n− type epitaxial layer 13A and low impurity concentration n− type epitaxial layer 13B. In the semiconductor device according to the first embodiment, in contrast to the semiconductor device of the second comparative, the two-layer structure of high concentration n− type epitaxial layer 13A and low concentration n− type epitaxial layer 13B does not extend to surround the termination unit, and this bi-layer structure terminates at the termination unit such that at least a portion of the termination trench 14F is in contact with n-low layer 13B.

Low concentration n− type epitaxial layer 13B, in the same way as n− type epitaxial layer 13 in the second comparative example, has in this example a degree of impurity concentration of 1×10¹⁵ [atoms/cm³]. High concentration n− type epitaxial layer 13A has a higher or larger large impurity concentration as compared to that of low concentration n− type epitaxial layer 13B, in this example an impurity concentration on the order of 1×10¹⁶ [atoms/cm³].

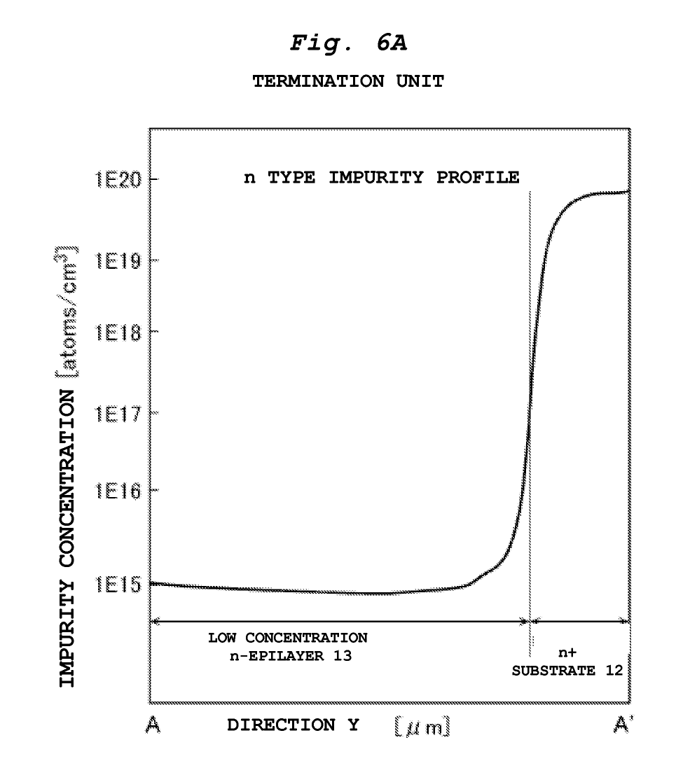

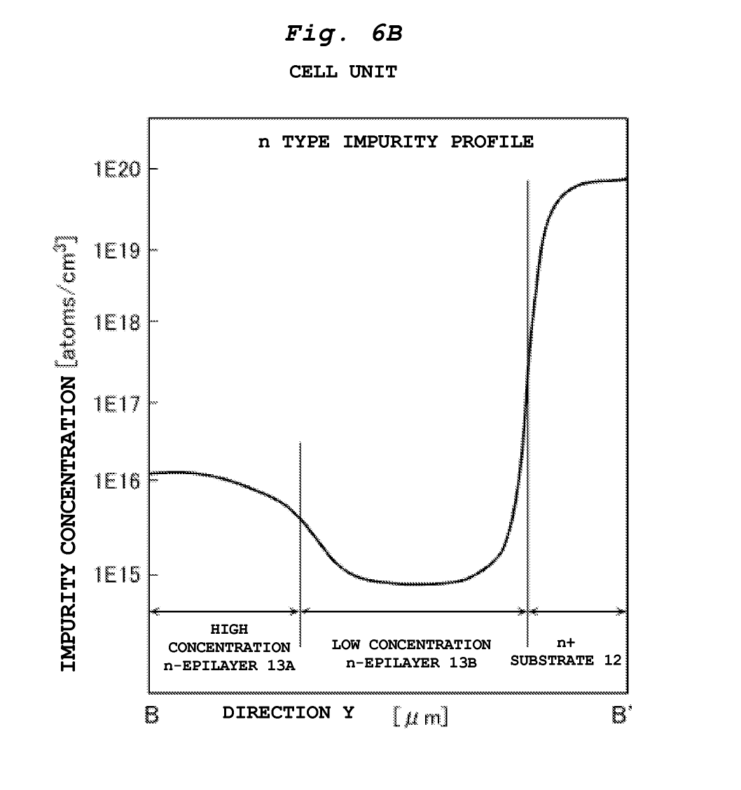

FIGS. 6A and 6B are graphs showing n type impurity concentration along the lines A—A′ and B-B′ in the termination unit and the cell unit of the first embodiment shown in FIGS. 5A and 5B. The vertical axes of FIGS. 6A and 6B show impurity concentrations and the horizontal axes show the positions of direction Y shown in FIGS. 5A and 5B. As shown in FIGS. 6A and 6B, n+ type semiconductor substrate 12 in the termination unit and the cell unit can have an n type impurity concentration of 1×10²° [atoms/cm³]. Low concentration n− type epitaxial layer 13B in the cell unit has an n type impurity concentration of 1×10¹⁵ [atoms/cm³], and high concentration n− type epitaxial layer 13A has an n type impurity concentration of 1×10¹⁶ [atoms/cm³]. n− type epitaxial layer 13 in the termination unit, for example, is an extension of low impurity concentration n− layer 13B and thus has the same impurity concentration of 1×10¹⁵ [atoms/cm³].

In the semiconductor device in the first embodiment, n-type epitaxial layer 13 in cell unit is divided into two layers which are high impurity concentration n− type epitaxial layer 13A and low impurity concentration n− type epitaxial layer 13B. This results in reduced on-resistance because high concentration n− type epitaxial layer 13A is formed up to immediately below trenches 14 of the cell unit. Alternatively, high concentration n− type epitaxial layer 13A is not formed in the termination unit. As a result, the breakdown voltage of the termination unit is not lower than the breakdown voltage of the cell unit, and the inherent reduction in avalanche resistance in prior art devices which occurred as a result of reducing on resistance is be prevented.

It should be noted that the impurity concentration of high concentration n− type epitaxial layer 13A in the cell unit can be arbitrarily set in a range such as 1×10¹⁵ to 1×10¹⁷ [atoms/cm³] to reduce the on-resistance. The impurity concentration of low concentration n− type epitaxial layer 13B in the cell unit or n− type epitaxial layer 13 in the termination unit can be arbitrarily set in a range such as 1×10¹⁴-1×10¹⁶ [atoms/cm³], but lower than the impurity concentration in layer 13A, to improve the avalanche resistance where the on resistance has been lowered with the high concentration over low concentration n− bi-layer 13.

### Embodiment 2

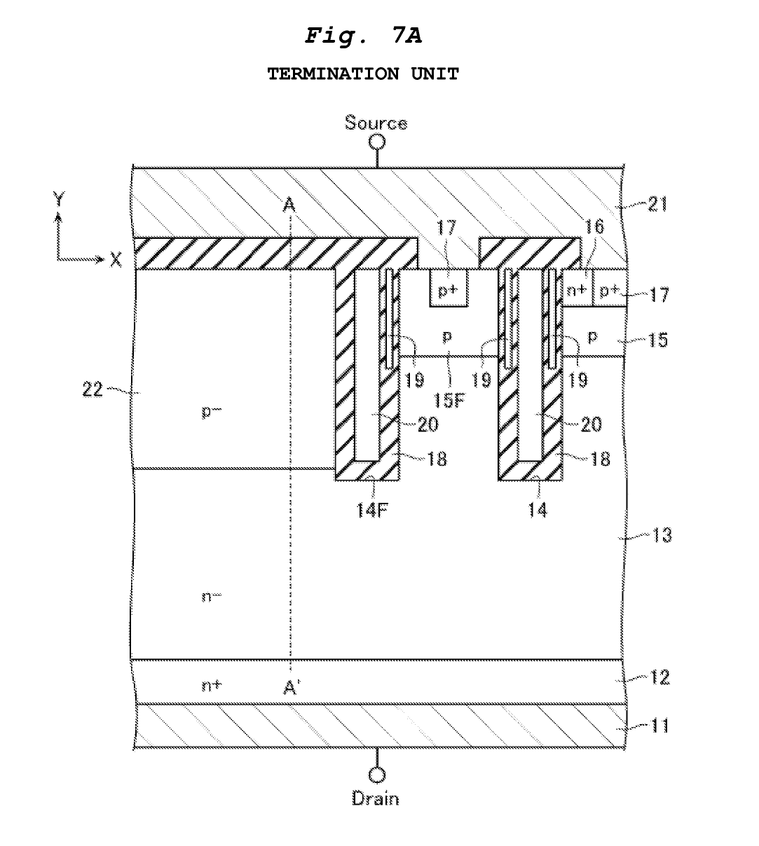

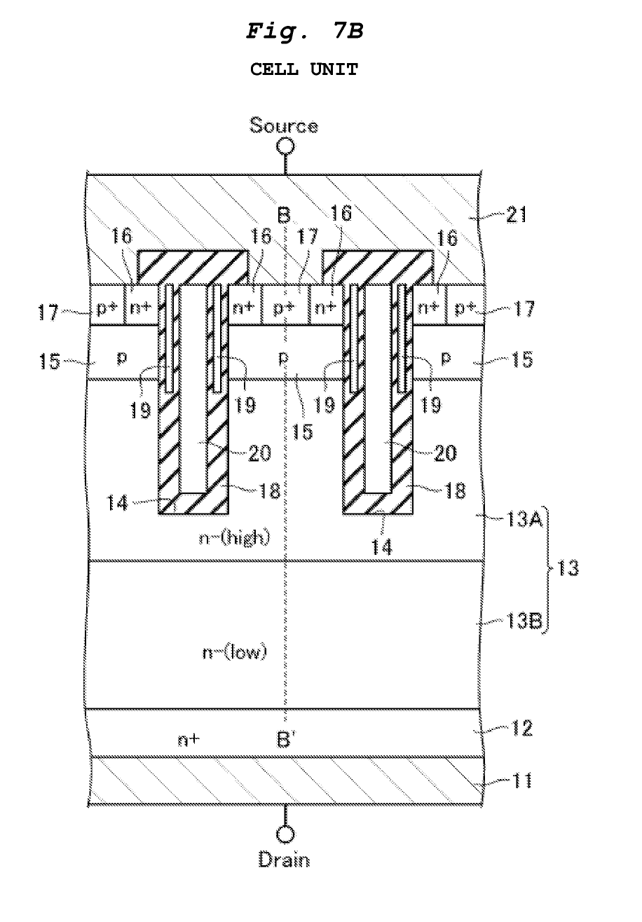

Referring now to FIGS. 7A and 7B, an additional embodiment of the reduced on-resistance but sufficient avalanche resistance structure is shown. As shown in FIG. 7A and FIG. 7B, the semiconductor device according to the second embodiment also includes a cell unit which functions as a MOSFET and a terminal unit provided on the periphery of the cell unit. It should be noted that in the second embodiment shown in FIGS. 7A and 7B, the parts that have the same structure as the first and the second comparative examples and duplicate descriptions denoted by the same reference numerals, will be omitted.

As shown in FIGS. 7A and 7B, the second embodiment is different from the first embodiment because of the structure of the termination unit. In the second embodiment, on the outer non-unit cell or termination side of trench 14F, p− type diffusion layer 22 is formed. This p− type diffusion layer 22 is formed over n− type epitaxial layer 13 only to the non-cell side of the termination cell 14F, and thus the base and unit cell side of termination trench 14F is in contact with the same n− layer which extends under, and in contact with portions of, the unit cells, and impurity concentration of about 1×10¹⁵ to 1×10¹⁶[atoms/cm³]. The p− type diffusion layer 22 may be formed by ion implantation of p type impurities into the n-layer 13 and subsequent annealing.

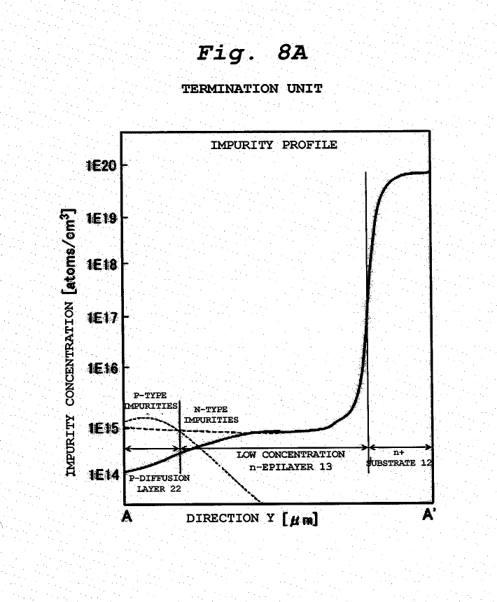

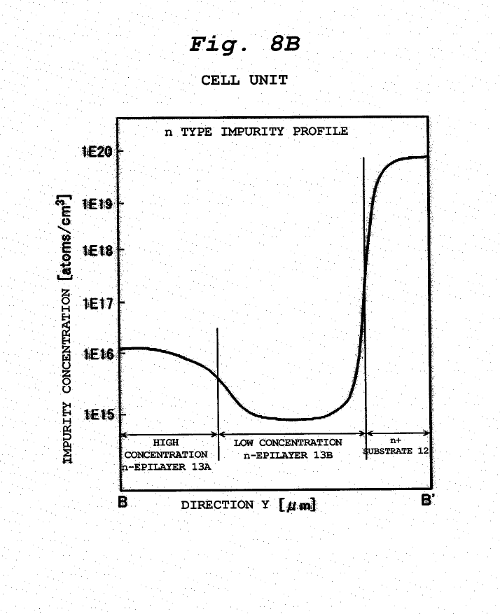

FIGS. 8A and 8B are graphs showing n type impurity concentration along the lines A-A′ and B-B′ in the termination unit and the cell unit of the second embodiment shown in FIGS. 7A and 7B. The vertical axes of FIGS. 8A and 8B show impurity concentrations and the horizontal axes show the position of direction Y shown in FIGS. 7A and 7B. As shown in FIGS. 8A and 8B, n+ type semiconductor substrate 12 in termination unit and cell unit can have a degree of n type impurity concentration of 1×10²° [atoms/cm]. Low concentration n− type epitaxial layer 13B in the cell unit can have a degree of n type impurity concentration of 1×10¹⁵ [atoms/cm³], for example, and high concentration n− type epitaxial layer 13A can have a degree of n type impurity concentration of 1×10¹⁶ [atoms/cm³], for example.

In the semiconductor device in this embodiment, p− type diffusion layer 22 is provided on n− type epitaxial layer 13 in the termination unit. The curve of n type impurity concentration in the terminal unit and the curve of the p type impurity concentration are represented by a dashed line and the curve of effective impurity concentration is represented in a solid line. n− type epitaxial layer 13 in the termination unit can have the degree of n type impurity concentration of 1×10¹⁵ [atoms/cm³], for example, and p− type diffusion layer 22 can have a degree of p type impurity concentration of 1×10¹⁵ to 1×10¹⁶ [atoms/cm³], for example. In this case, p− type diffusion layer 22 will either become a low concentration p-type layer by offsetting the effect of the n− type impurity in the n− layer 13 from which it is formed. The p type impurity concentration of p− type diffusion layer 22 is set so as to have the effective n type impurity inside p-type diffusion layer 22 in the range of 1×10¹³ to 1×10¹⁵ [atoms/cm³].

In the semiconductor device in the second embodiment, n− type epitaxial layer 13 in the cell unit is divided into two layers which are high concentration n− type epitaxial layer 13A and low concentration n− type epitaxial layer 13B. Due to this, on-resistance is reduced in comparison to an n− layer of a single impurity concentration, because high concentration n− type epitaxial layer 13A is formed up to immediately below trenches 14 in the cell unit. However, at the termination unit, on n− type epitaxial layer 13, p− type diffusion layer 22 is formed. Therefore, the breakdown voltage of the termination unit is further improved than in the first embodiment, and avalanche resistance can be improved as compared to having an n− bi-layer extend past the termination unit 14F.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first region which functions as a MOSFET; and
a second region which is adjacent to the first region;
the first region comprising,
a drain electrode of the MOSFET;
a semiconductor substrate of a first conductivity type which has a first impurity concentration while being electrically connected to the drain electrode;
a first semiconductor layer on the semiconductor substrate of the first conductivity type which has a second impurity concentration which is lower than the first impurity concentration;
a second semiconductor layer having a first surface side contacting the first semiconductor layer and a second side opposed to the first side on the first semiconductor layer of the first conductivity type which has a third impurity concentration which is lower than the first impurity concentration but higher than the second impurity concentration;
a plurality of first trenches extending into the second side of the second semiconductor layer;
a third semiconductor layer on the second semiconductor layer of the second conductivity type, which is adjacent to the first trenches;
a fourth semiconductor layer on the third semiconductor layer of the first conductivity type which is adjacent to the first trenches;
a first insulating layer which is formed along inner walls of the first trenches;
a gate electrode opposed to the third semiconductor layer through the first insulating layer;
a trench electrode extending inwardly of the first trenches through the first insulating layer; and
a source electrode which contacts the fourth semiconductor layer and which is electrically connected to the trench source electrode layer, and
the second region comprising:
the semiconductor substrate;
the first semiconductor layer;
the first insulating layer formed in order to extend to the upper face of the first semiconductor layer; and
the source electrode,
wherein the first semiconductor layer of the second region has the second impurity concentration.

2. The semiconductor device according to claim 1, further comprising:
diffusion layers of the second conductivity type located on the surface of the first semiconductor layer and are placed on the second region.

3. The semiconductor device according to claim 2, wherein
the impurity concentration of the second conductivity type of the diffusion layer is set to be in the range of 1×10¹³-1×10¹⁵ [atoms/cm³].

4. The semiconductor device according to claim 1, wherein
the second impurity concentration is set in the range of 1×10¹⁴ to 1×10¹⁶ [atoms/cm³], and
the third impurity concentration is set in the range of 1×10¹⁵ to 1×10¹⁷ [atoms/cm³].

5. The semiconductor device according to claim 1, wherein
the second semiconductor layer is formed to reach below the bottom surface of the first trenches, and
the trenches are formed to extend into the second semiconductor layer.

6. A semiconductor device having a plurality of unit cells having trenches extending inwardly of a first conductivity type doped region formed over a substrate wherein the unit cells are bounded by a termination cell second having a trench extending inwardly of the first conductivity type doped layer, comprising:
the first conductivity type doped layer into which at least one unit cell extends includes a first doped region of a first conductivity type and a second doped region of a first conductivity type overlying. first doped region, the first doped region having a property different than the property of the second doped region; and
the doped layer into which the termination cell extends includes a first doped region and a second doped region overlying the first doped region in the area between the termination cell and the substrate and the area between the termination cell and the adjacent unit cell, and a different property adjacent the side of the trench which is not adjacent to unit cell.

7. The semiconductor device of claim 6, wherein the property of the first and second doped regions is a lower impurity concentration in the first region than the impurity concentration in the second region.

8. The semiconductor device of claim 7, wherein the first region is a sub layer of the first doped layer in contact with the substrate.

9. The semiconductor device of claim 8, wherein the second region is a sub-layer of the first doped layer disposed on the first region of the first doped layer having a first side contacting the first region and a second side.

10. The semiconductor device of claim 9, wherein the trenches extend inwardly of the first side of the second region and terminate within the second region.

11. The semiconductor device of claim 7, Wherein the property of the first doped layer adjacent to the side of the trench which is not adjacent to unit cell is the impurity concentration of the first region.

12. The semiconductor device of claim 7, wherein the property of the doped layer adjacent to the side of the trench which is not adjacent to a unit cell is an impurity of a second, opposed, conductivity type from the first type.

13. The semiconductor device of claim 12, wherein a layer adjacent to the side of the trench which is not adjacent to a unit cell contacts the trench.

14. The semiconductor device of claim 12, wherein the layer adjacent to the side of the trench which is not adjacent to a unit cell also includes the impurity concentration of the first region.

15. The semiconductor device of claim 12, wherein the layer adjacent to the side of the trench which is not adjacent to a unit cell contacts the trench.

16. The semiconductor device of claim 7, wherein:
the trenches of the unit cells and the termination unit include an insulating layer thereon; and
a gate electrode extends inwardly of the trench, from the second side of the second region inwardly of the trench and is surrounded by the insulating layer.

17. The semiconductor device of claim 16, further including a source electrode extending within the trench, and spaced from the gate electrode from the insulating layer.

18. A method of reducing on resistance of a MOSFET device while reducing a decrease in the avalanche resistance of the device, comprising:
providing a semiconductor layer;
providing a plurality of unit cells having trenches extending inwardly of a the semiconductor layer;
doping the semiconductor layer in the region of the unit cells to include ea bi-layer having a first, lower impurity concentration layer and a second, higher impurity concentration layer overlying the first layer, wherein the trenches terminate within the second layer;
providing a termination cell having a trench extending inwardly of the semiconductor layer at a location adjacent to a final unit cell in a plurality of unit cells;
extending the bi-layer of the semiconductor layer to contact at least the sidewall of the trench of the termination cell which is adjacent to the unit cells; and
providing a different property in the semiconductor layer at the side of the trench opposed to the unit cells than the property of the semiconductor layer contacting the sidewall of the trench at the side of the trench adjacent to the unit cells.

19. The method of reducing on resistance of a MOSFET device while reducing a decrease in the avalanche resistance of the device of claim 18, further including providing the impurity concentration of the first layer as the different property in the semiconductor layer at the side of the trench opposed to the unit cells.

20. The method of reducing on resistance of a MOSFET device while reducing a decrease in the avalanche resistance of the device of claim 18, further including providing the impurity of an opposed conductivity type than the impurity of the first layer as the different property in the semiconductor layer at the side of the trench opposed to the unit cells.
